(19) United States
(12) Patent Application Publication
(10) Pub. No.: US 2023/0059828 A1
(43) Pub. Date: Feb. 23, 2023

(54) TRANSISTOR AND METHOD FOR MANUFACTURING SAME

(71) Applicant: CHANGXIN MEMORY TECHNOLOGIES, INC., Hefei City (CN)

(72) Inventor: Xiang LIU, Hefei City (CN)

(73) Assignee: CHANGXIN MEMORY TECHNOLOGIES, INC., Hefei City (CN)

(21) Appl. No.: 17/808,292

(22) Filed: Jun. 22, 2022

Related U.S. Application Data
(63) Continuation of application No. PCT/CN2021/128083, filed on Nov. 2, 2021.

(30) Foreign Application Priority Data
Aug. 20, 2021 (CN) 202110959684.8

(51) Int. Cl. H01L 29/78; H01L 29/66

(52) U.S. Cl. CPC H01L 29/7813; H01L 29/66621; H01L 29/66704

(57) ABSTRACT

A transistor comprises a substrate; a gate trench located in the substrate; a first gate layer located in the gate trench, and a material of the first gate layer comprising TiN or comprising W; a second gate layer located in the gate trench and covering the first gate layer, a material of the second gate layer comprising TiNx, wherein 0 ≤ x< 1, and a work function of the second gate layer being smaller than a work function of the first gate layer.

### CROSS-REFERENCE TO RELATED APPLICATIONS

This application is a continuation application of International Application No. PCT/CN2021/128083 filed on Nov. 2, 2021, which claims priority to Chinese Patent Application No. 202110959684.8 filed on Aug. 20, 2021. The disclosures of these applications are hereby incorporated by reference in their entirety.

### BACKGROUND

The metal oxide semiconductor (MOS) transistor is an important element in the manufacture of integrated circuits. MOS transistors may be used to form a memory, such as an access transistor used as a dynamic random access memory (DRAM), in which the gate is connected to the word line, one end of the access transistor is connected to a bit line, and the other end is connected to a storage capacitor, which is typically used to store charges representative of stored information.

At present, the access transistor of DRAM usually adopts a buried word line (BW), but it is prone to lead gate-induced drain leakage (GIDL) when manufacturing the BW.

### SUMMARY

The present disclosure relates to, but is not limited to, a transistor and a method for manufacturing the same.

In view of this, the embodiments of the disclosure provide a transistor and a method for manufacturing the same.

According to a first aspect of embodiments of the present disclosure, a transistor is provided, and the transistor includes:
a substrate;
a gate trench located in the substrate;
a first gate layer located in the gate trench; a material of the first gate layer including TiN;
a second gate layer located in the gate trench and covering the first gate layer; a material of the second gate layer including TiNₓ, where 0 ≤ x< 1; a work function of the second gate layer being smaller than a work function of the first gate layer.

According to a second aspect of embodiments of the present disclosure, a transistor is provided, and the transistor includes:
a substrate;
a gate trench located in the substrate;
a first gate layer located in the gate trench; a material of the first gate layer including tungsten;
a second gate layer located in the gate trench and covering the first gate layer; a material of the second gate layer including TiNₓ, where 0 ≤ x< 1; a work function of the second gate layer being smaller than a work function of the first gate layer.

According to a third aspect of embodiments of the present disclosure, a method for manufacturing a transistor is provided, and the method includes:
providing a substrate;
etching the substrate to form a gate trench;
forming a first gate layer in the gate trench; a material of the first gate layer including TiN;
forming a second gate layer covering the first gate layer in the gate trench; a material of the second gate layer including TiNₓ, where 0 ≤ x< 1; a work function of the second gate layer being smaller than a work function of the first gate layer.

According to a forth aspect of embodiments of the present disclosure, a method for manufacturing a transistor is provided, and the method includes:
providing a substrate;
etching the substrate to form a gate trench;
forming a first gate layer in the gate trench; a material of the first gate layer including tungsten; and
forming a second gate layer covering the first gate layer in the gate trench; a material of the second gate layer including TiNₓ, where 0 ≤ x< 1; a work function of the second gate layer being smaller than a work function of the first gate layer.

### BRIEF DESCRIPTION OF THE DRAWINGS

FIG. 1A is a schematic structural diagram of a transistor in some implementations;

FIG. 1B is a first graph showing the relationship between the height of polysilicon and the resistance of word lines in some implementations;

FIG. 1C is a second graph showing the relationship between the height of polysilicon and the resistance of word lines in some implementations;

FIG. 2 is a schematic structural diagram of a transistor provided by an embodiment of the disclosure;

FIG. 3 is a graph showing the functional relationship of the work function of TiNₓ to the N₂ gas flow and the substrate temperature during reactive sputtering deposition;

FIG. 4 is a graph showing the functional relationship between thickness of the equivalent oxide layer and the flat band voltage.

FIG. 5 is a schematic structural diagram of a transistor provided by another embodiment of the disclosure;

FIG. 6 is a flow chart of a method for manufacturing a transistor provided by an embodiment of the disclosure;

FIG. 7A is a first schematic structural diagram of a device in the process of manufacturing a transistor provided by embodiments of the disclosure;

FIG. 7B is a second schematic structural diagram of a device in the process of manufacturing a transistor provided by embodiments of the disclosure;

FIG. 7C is a third schematic structural diagram of a device in the process of manufacturing a transistor provided by embodiments of the disclosure;

FIG. 7D is a fourth schematic structural diagram of a device in the process of manufacturing a transistor provided by embodiments of the disclosure;

FIG. 7E is a fifth schematic structural diagram of a device in the process of manufacturing a transistor provided by embodiments of the disclosure;

FIG. 7F is a sixth schematic structural diagram of a device in the process of manufacturing a transistor provided by embodiments of the disclosure;

FIG. 7G is a seventh schematic structural diagram of a device in the process of manufacturing a transistor provided by embodiments of the disclosure;

FIG. 7H is an eighth schematic structural diagram of a device in the process of manufacturing a transistor provided by embodiments of the disclosure;

FIG. 7I is a ninth schematic structural diagram of a device in the process of manufacturing a transistor provided by embodiments of the disclosure;

FIG. 8 is a flow chart of a method for manufacturing a transistor provided by another embodiment of the disclosure;

FIG. 9A is a first schematic structural diagram of a device in the process of manufacturing a transistor provided by embodiments of the disclosure;

FIG. 9B is a second schematic structural diagram of a device in the process of manufacturing a transistor provided by embodiments of the disclosure;

FIG. 9C is a third schematic structural diagram of a device in the process of manufacturing a transistor provided by embodiments of the disclosure;

FIG. 9D is a fourth schematic structural diagram of a device in the process of manufacturing a transistor provided by embodiments of the disclosure;

FIG. 9E is a fifth schematic structural diagram of a device in the process of manufacturing a transistor provided by embodiments of the disclosure;

FIG. 9F is a sixth schematic structural diagram of a device in the process of manufacturing a transistor provided by embodiments of the disclosure;

FIG. 9G is a seventh schematic structural diagram of a device in the process of manufacturing a transistor provided by embodiments of the disclosure;

FIG. 9H is an eighth schematic structural diagram of a device in the process of manufacturing a transistor provided by embodiments of the disclosure; and

FIG. 9I is a ninth schematic structural diagram of a device in the process of manufacturing a transistor provided by embodiments of the disclosure.

### DETAILED DESCRIPTION

Exemplary embodiments of the present disclosure will be described in more detail below with reference to the accompanying drawings. Although exemplary embodiments of the present disclosure are shown in the drawings, it should be understood that the present disclosure may be implemented in various forms and should not be limited to the specific embodiments set forth herein. These embodiments are provided so that the disclosure will be more thoroughly understood and the scope of the disclosure will be fully conveyed to those skilled in the art.

In the description herein below, numerous specific details are given to provide a more thorough understanding of the disclosure. However it will be apparent to those skilled in the art that the disclosure may be implemented without one or more of these details. In other examples, some technical features well-known in the art are not described in order to avoid confusion with the present disclosure; that is, not all of the features of actual embodiments are described herein, and well-known functions and structures are not described in detail.

In the drawings, the dimensions of layers, regions, elements and their relative dimensions may be exaggerated for clarity. The same reference numeral denotes the same element throughout the text.

It should be understood that when an element or a layer is referred to as “on”, “adjacent to”, “connected to” or “coupled to” another element or layer, it may be directly on the other element or layer, adjacent to the other element or layer, or connected to or coupled to the other element or layer, or there may be an intermediate element or layer therebetween. In contrast, when an element is described as “directly on”, “directly adjacent to”, “directly connected to” or “directly coupled to” another element or layer, there is no intermediate element or layer therebetween. It should be understood that although the terms, “first”, “second”, “third” and the like may be used to describe various elements, components, regions, layers, and/or portions, these elements, components, regions, layers, and/or portions should not be limited by these terms. These terms are only used to distinguish one element, component, region, layer or portion from another element, component, region, layer or portion. Therefore, without departing from the teaching of the present disclosure, a first element, component, region, layer or portion discussed hereinafter may be expressed as a second element, component, region, layer or portion. While discussing a second element, component, region, layer or portion, it does not imply that a first element, component, region, layer or portion is necessarily present in the present disclosure.

Spatial relationship terms such as “beneath”, “below”, “lower”, “under”, “above”, or “upper” may be used herein for convenience to describe a relationship between one element or feature and another element or feature shown in the drawings. It should be understood, the spatial relationship terms intend to further include different orientations of a device in use and operation in addition to the orientations shown in the drawings. For example, if the device in the drawings is turned over, an element or feature described as being “below” or “under” or “beneath” another element will be oriented as being “above” the other element or feature. Therefore, the exemplary terms “below” and “under” may include up and down orientations. The device may also include additional orientations (e.g., rotation for 90 degrees or other orientations), and the spatial terms used herein are interpreted accordingly.

The terms used herein are intended to describe specific embodiments only and are not to be a limitation to the present disclosure. As used herein, the singular forms “a/an”, “one”, and “the/said” are intended to include the plural forms as well, unless the context clearly dictates otherwise. It should be further understood that when terms “consist of” and/or “comprise/include” used in the specification mean that the stated features, integers, steps, operations, elements and/or components are present, but the presence or addition of one or more of other features, integers, steps, operations, elements, components and/or combinations is not excluded. When used herein, the term “and/or” includes any of the listed items and all combinations thereof.

In order to thoroughly understand the present disclosure, detailed operations and structures will be set forth in the following description in order to illustrate the technical solution of the present disclosure. Preferred embodiments of the present disclosure are described in detail below. However, the present disclosure may have other embodiments in addition to these detailed descriptions.

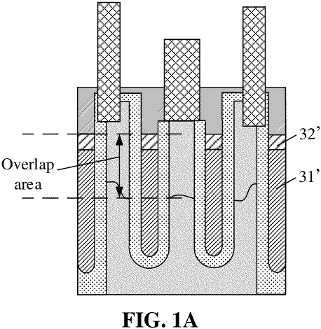

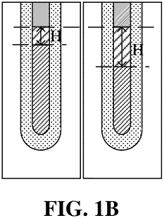

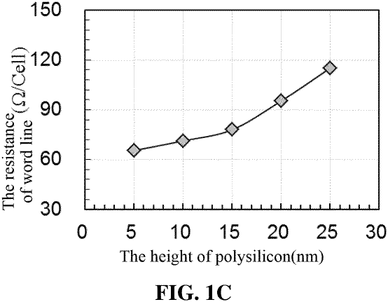

In some implementations, GIDL is a main approach of DRAM electric leakage. The magnitude of the GIDL depends directly on the electric field in the drain overlap area between the word line and the drain, in particular, as shown in FIG. 1A. In a more advanced process, polysilicon with lower work function is used to replace a part of the metal word line with higher work function, that is, the material of the second gate layer 32' as shown in FIG. 1A is polysilicon, and the material of the first gate layer 31' is TiN or W, so that the electric field in this region can be effectively reduced and the GIDL can be reduced. This is the dual work function gate structure adopted by various companies.

The more metal word lines replaced by polysilicon, the less GIDL. However, since the resistivity of polysilicon is about two orders of magnitude larger than that of TiN or W, as shown in FIG. 1B, the higher the height H of polysilicon, the greater the resistance of the word line. The specific calculation results are shown in FIG. 1C. The magnitude of the resistance of the word line is directly related to the speed at which the access transistor is turned on, which will lead to a series of problems. For example, in order to ensure the speed, the length of word line must be shortened, which will limit the size of the memory array and affect the area of the chip.

Moreover, in the high temperature process of the peripheral circuit, such as growing a gate oxide layer or doping annealing, polysilicon will react with W at high temperature to form WSi at the interface, which affects the quality of the interface, further increases the resistance, and reduce the quality of polysilicon and the actual effect of dual gate.

In addition, polysilicon needs to be doped, and the process is complicated. When the voltage of the bottom metal word line changes, the doped polysilicon will form a metal-semiconductor contact and produce a depletion layer, which is not conducive to the RC characteristics of the word line and the efficiency of the dual gate.

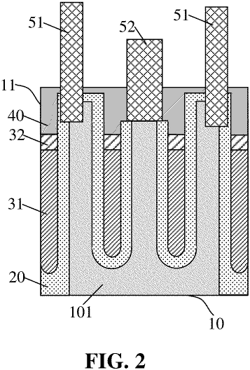

In view of this, the embodiments of the disclosure provide a transistor. FIG. 2 is a schematic structural diagram of a transistor provided by an embodiment of the disclosure.

Referring to FIG. 2, the transistor includes a substrate 10; a gate trench 11 located in the substrate 10; a first gate layer 31 located in the gate trench 11, in which the material of the first gate layer 31 includes TiN; a second gate layer 32 located in the gate trench 11 and covering the first gate layer 31, in which the material of the second gate layer 32 includes TiNx, where 0 ≤ x< 1, and the work function of the second gate layer 32 is smaller than the work function of the first gate layer 31.

In the embodiments of the present disclosure, TiN with a higher work function is used at the bottom end of the gate trench, and TiNₓ with a lower work function is used at the top end of the gate trench, which effectively reduces the electric field in the gate trench, and reduces the GIDL. In addition, compared with using polysilicon as the material of the second gate layer in some implementations, TiNₓ has a smaller resistivity compared to polysilicon and has a better conductivity, which is more conducive to forming longer word lines, increasing the area of the memory array of the transistor and reducing the size of the chip.

In addition, since TiNₓ and TiN are homogeneous material, compared with some implementations using polysilicon as the material of the second gate layer, the structure provided by the embodiments of the present disclosure has better process compatibility, and also eliminates the heterogeneous interface between the metal word line and polysilicon, thereby reducing the generation of metal semiconductor contact.

In an embodiment, the substrate may be an elemental semiconductor material substrate (such as a silicon (Si) substrate, a germanium (Ge) substrate, etc.), a compound semiconductor material substrate (such as a silicon germanium (SiGe) substrate, etc.), or a silicon on insulator (SOI) substrate, a germanium on insulator (GeOI) substrate, etc.

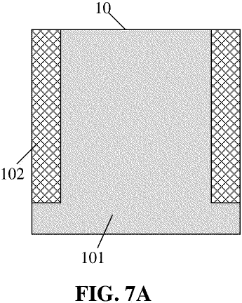

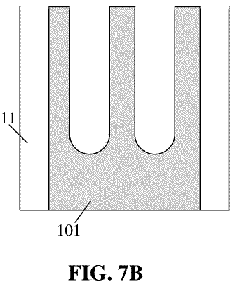

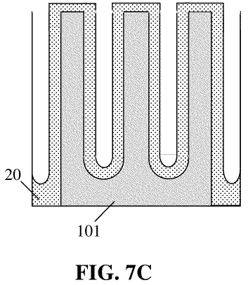

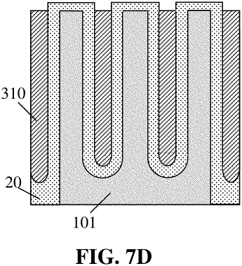

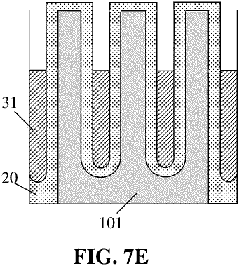

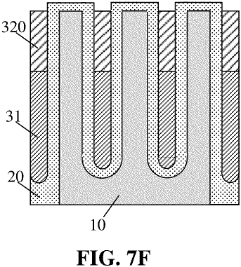

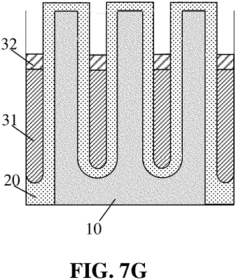

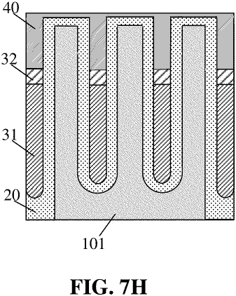

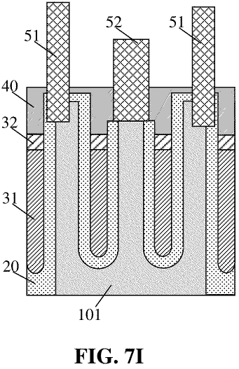

The substrate 10 further includes an isolation layer 102, in particular, with reference to FIG. 7A, the isolation layer 102 defines the active areas 101.

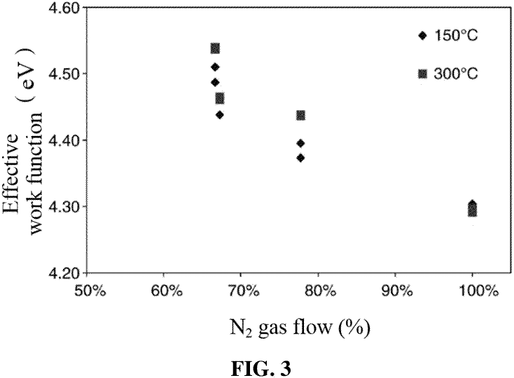

In the embodiments of the disclosure, the content of N in TiNₓ can be achieved by controlling the flow of N₂ during forming the second gate layer. Compared with using polysilicon as the material of the second gate layer, the process for forming word line is simplified. FIG. 3 is a graph showing the functional relationship of the work function of TiN_{X} to the N₂ gas flow and the substrate temperature during reactive sputtering deposition. Referring to FIG. 3, the work function of TiNₓ may be allowed to change about 0.30 eV by changing the content of N in TiN.

In an embodiment, the x is equal to 0, and the material of the second gate layer 32 includes Ti. That is, in the process for forming the second gate layer 32, N₂ is not introduced. Therefore, the material of the second gate layer 32 is Ti.

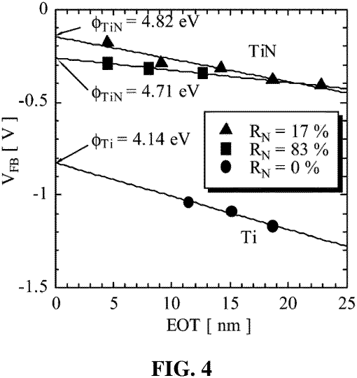

FIG. 4 is a graph showing the functional relationship between thickness of the equivalent oxide layer and the flat band voltage. EOT shown in the graph is the thickness of the equivalent oxide layer, and V_{FB} is flat band voltage. As shown in the FIG. 4, when the ratio of N (R_{N}) increases from 0% to 17%, the work function of TiNₓ is effectively controlled between 4.14 and 4.82 eV. When R_{N} further increases to 83%, the work function of TiNₓ decreases slightly to 4.71 eV. When R_{N} is equal to 0, it is Ti. As can be seen from the figure, the work function of Ti is about 0.5-0.6 eV lower than the work function of TiNₓ. Therefore, using Ti as the material of the second gate layer, a second gate layer with a lower work function can be obtained, and Ti has better conductivity than polysilicon in some implementations.

In an embodiment, the material of the second gate layer 32 includes a mixed material of TiNₓ and Ti, where 0<x<1.

In an embodiment, the transistor further includes a gate dielectric layer 20 which covers the sidewall and bottom surface of the gate trench 11. The gate dielectric layer 20 further covers the surface of part of the substrate 10.

The gate dielectric layer 20 wraps the sidewall and bottom surface of the first gate layer 31 and the sidewall of the second gate layer 32.

The gate dielectric layer 20 may include silica or a high-K dielectric material.

In an embodiment, the transistor further includes an insulating dielectric layer 40, which covers the second gate layer 32 and fills up the gate trench 11.

The insulating dielectric layer 40 may include silicon nitride, silicon oxide, silicon oxynitride, other insulating material or any combination thereof.

In an embodiment, the transistor further includes a contact plug, which is located on the substrate 10.

The contact plug includes a first contact plug 51 and a second contact plug 52. The first contact plug 51 may also be referred to as a source/drain contact plug, and may be electrically coupled to the source/drain. The second contact plug 52 may also be referred to as a gate contact plug, and may be electrically coupled to the metal gate.

The contact plug may include polysilicon, metal silicide, metal nitride or metal.

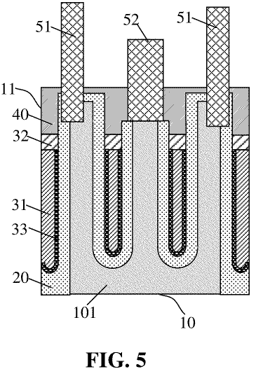

The embodiments of the disclosure also provide a transistor. FIG. 5 is a schematic structural diagram of a transistor provided by another embodiment of the disclosure.

Referring to FIG. 5, the transistor includes a substrate 10; a gate trench 11 located in the substrate 10; a first gate layer 31 located in the gate trench 11, in which the material of the first gate layer 31 includes tungsten; a second gate layer 32 located in the gate trench 11 and covering the first gate layer 31, in which the material of the second gate layer 32 includes TiNₓ, where 0 < x< 1, and the work function of the second gate layer 32 is smaller than the work function of the first gate layer 31.

In the embodiments of the present disclosure, tungsten with a higher work function is used at the bottom end of the gate trench, and TiNₓ with a lower work function is used at the top end of the gate trench, which effectively reduces the electric field in the gate trench, and reduces the GIDL. In addition, compared with using polysilicon as the material of the second gate layer in some implementations, TiNₓ has a smaller resistivity compared to polysilicon and has a better conductivity, which is more conducive to forming a longer word line, increasing the area of the memory array of the transistor and reducing the size of the chip.

In an embodiment, the substrate may be an elemental semiconductor material substrate (such as a silicon (Si) substrate, a germanium (Ge) substrate, etc.), a compound semiconductor material substrate (such as a silicon germanium (SiGe) substrate, etc.), or a silicon on insulator (SOI) substrate, a germanium on insulator (GeOI) substrate, etc.

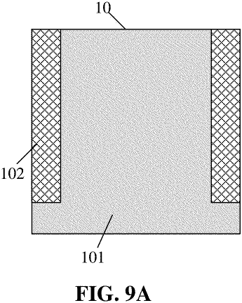

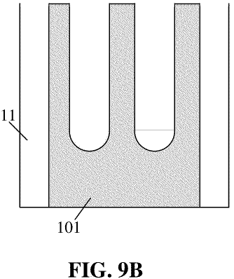

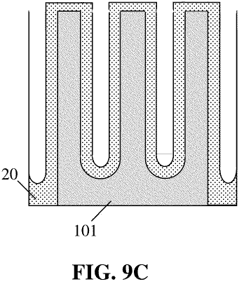

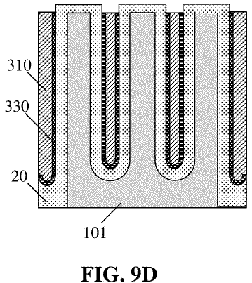

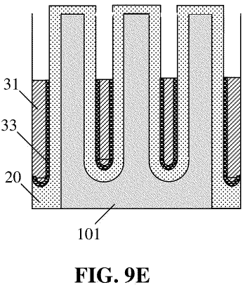

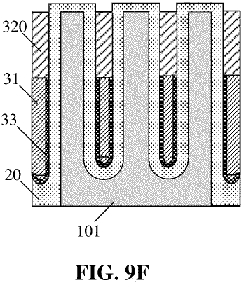

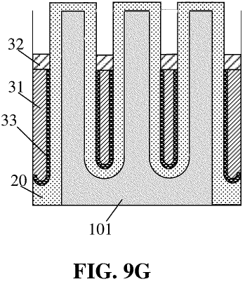

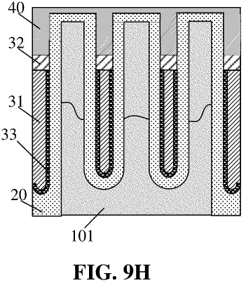

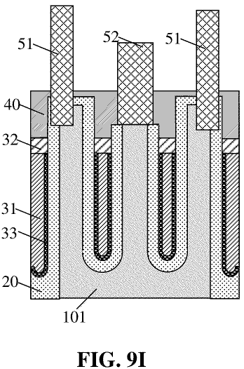

The substrate 10 further includes an isolation layer 102, in particular, with reference to FIG. 9A, the isolation layer 102 defines the active area 101.

In the embodiments of the disclosure, the content of N in TiNₓ can be achieved by controlling the flow of N₂ during forming the second gate layer. Compared with using polysilicon as the material of the second gate layer, the process for forming word line is simplified. FIG. 3 is a graph showing the functional relationship of the work function of TiNₓ to the N₂ gas flow and the substrate temperature during reactive sputtering deposition. Referring to FIG. 3, the work function of TiNₓ may be allowed to change about 0.30 eV by changing the content of N in TiN.

In an embodiment, the x is equal to 0, and the material of the second gate layer 32 includes Ti. That is, in the process for forming the second gate layer, N₂ is not introduced. Therefore, the material of the second gate layer 32 is Ti.

FIG. 4 is a graph showing the functional relationship between thickness of the equivalent oxide layer and the flat band voltage. EOT shown in the graph is the thickness of the equivalent oxide layer, and V_{FB} is flat band voltage. As shown in the FIG. 4, when the ratio of N (R_{N}) increases from 0% to 17%, the work function of TiNₓ is effectively controlled between 4.14 and 4.82 eV. When R_{N} further increases to 83%, the work function of TiNₓ decreases slightly to 4.71 eV. When R_{N} is equal to 0, it is Ti. As can be seen from the figure, the work function of Ti is about 0.5-0.6 eV lower than the work function of TiNₓ. Therefore, using Ti as the material of the second gate layer, a second gate layer with a lower work function can be obtained, and Ti has better conductivity than polysilicon in some implementations.

In an embodiment, the material of the second gate layer 32 includes a mixed material of TiNₓ and Ti, where 0<x<1.

In an embodiment, the transistor further includes a barrier layer 33, which is located in the gate trench 11 and wraps the sidewall and the bottom of the first gate layer 31. The material of the barrier layer 33 includes TiN.

Since TiNₓ and TiN are homogeneous material, the structure can have better process compatibility, and the first gate layer and the barrier layer are better bonded with the second gate layer at the interface therebetween which is more conducive to improving the performance of the transistor.

The second gate layer 32 further covers the surface of the barrier layer 33.

In an embodiment, the transistor further includes a gate dielectric layer 20 which covers the sidewall and bottom surface of the gate trench 11. The gate dielectric layer 20 further covers the surface of part of the substrate 10.

The gate dielectric layer 20 wraps the sidewall and bottom surface of the barrier layer 33 and the sidewall of the second gate layer 32.

The gate dielectric layer 20 may include silica or a high-K dielectric material.

In an embodiment, the transistor further includes an insulating dielectric layer 40, which covers the second gate layer 32 and fills up the gate trench 11.

The insulating dielectric layer 40 may include silicon nitride, silicon oxide, silicon oxynitride, other insulating material or any combination thereof.

In an embodiment, the transistor further includes a contact plug, which is located on the substrate 10.

The contact plug includes a first contact plug 51 and a second contact plug 52. The first contact plug 51 may also be referred to as a source/drain contact plug, and may be electrically coupled to the source/drain. The second contact plug 52 may also be referred to as a gate contact plug, and may be electrically coupled to the metal gate.

The contact plug may include polysilicon, metal silicide, metal nitride or metal.

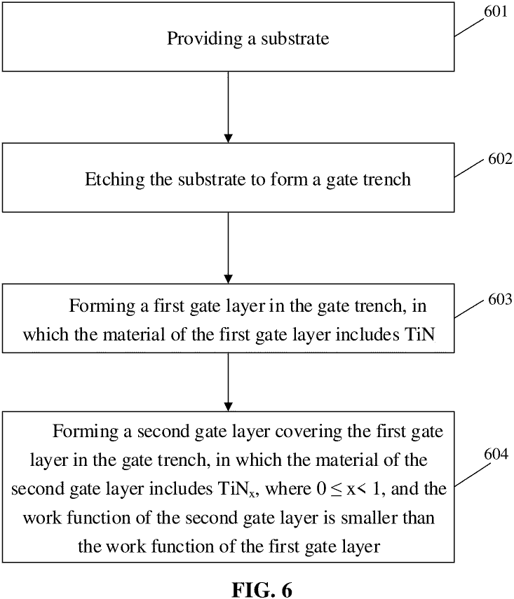

The embodiments of the present disclosure also provides a method for manufacturing a transistor, in particular, referring to FIG. 6, the method includes: the operation 601: providing a substrate; the operation 602: etching the substrate to form a gate trench; the operation 603: forming a first gate layer in the gate trench, in which the material of the first gate layer includes TiN; the operation 604: forming a second gate layer covering the first gate layer in the gate trench, in which the material of the second gate layer includes TiNₓ, where 0 ≤ x< 1, and the work function of the second gate layer is smaller than the work function of the first gate layer.

The method for manufacturing a transistor provided by the embodiments of the present disclosure will be described in further detail below in combination with specific embodiments.

FIGS. 7A to 7I are schematic structural diagrams of devices in the process of manufacturing a transistor provided by embodiments of the disclosure.

Firstly, referring to FIG. 7A, the operation 601 is performed, that is, the substrate 10 is provided.

In an embodiment, the substrate may be an elemental semiconductor material substrate (such as a silicon (Si) substrate, a germanium (Ge) substrate, etc.), a compound semiconductor material substrate (such as a silicon germanium (SiGe) substrate, etc.), or a silicon on insulator (SOI) substrate, a germanium on insulator (GeOI) substrate, etc. In the embodiments of the disclosure, the substrate may be a silicon substrate.

Before performing the operation 602, N-type doping is performed on the substrate 10 and an isolation layer 102 is formed in the substrate 10. The isolation layer 102 defines the active area 101. The isolation layer 102 may be formed by shallow trench isolation (STI) process. Specifically, the isolation trench may be formed by etching the substrate 10 and then the isolation trench is filled with a dielectric material to form the isolation layer 102.

The material of the isolation layer 102 includes silica or the like.

Subsequently, referring to FIG. 7B, the operation 602 is performed, that is, the substrate 10 is etched to form a gate trench 11.

Specifically, a mask layer may be firstly grown on the upper surface of the substrate 10, and then is patterned to display a pattern of a gate trench to be etched on the mask layer. The mask layer may be patterned by a photolithography process. The mask layer may be a photoresist mask or a hard mask which may be patterned based on a photolithography mask; when the mask layer is a photoresist mask, the mask layer is patterned through the operations of exposure, development, glue removal and the like. Next, the gate trench with a certain depth is obtained by etching according to the pattern of the gate trench to be etched.

During etching to form the gate trench 11, since the material of the isolation layer 102 is silica and the material of the substrate is silicon, and the etching selectivity ratio of silica and silicon is different, so that the depth of the gate trench 11 formed by etching the isolation layer 102 is deeper than the depth of the gate trench 11 formed by etching the substrate 10.

Subsequently, referring to FIG. 7C, a gate dielectric layer 20 is formed in the gate trench 11. The gate dielectric layer 20 covers the sidewall and bottom surface of the gate trench 11. The gate dielectric layer 20 further covers part of the surface of the substrate 10.

The gate dielectric layer 20 may include silica or a high-K dielectric material.

Next, referring to FIGS. 7D to 7E, a first gate layer 31 is formed in the gate trench 11. The material of the first gate layer 31 includes TiN.

Specifically, referring to FIG. 7D, a first gate material layer 310 is formed in the gate trench 11 and the first gate material layer 310 fills up the gate trench 11.

Then referring to FIG. 7E, the first gate material layer 310 is etched back to form the first gate layer 31.

Next, referring to FIGS. 7F to 7G, a second gate layer 32 covering the first gate layer 31 is formed in the gate trench 11. The material of the second gate layer 32 includes TiNₓ, where 0 ≤ x< 1. The work function of the second gate layer 32 is smaller than the work function of the first gate layer 31.

Specifically, referring firstly to FIG. 7F, a second gate material layer 320 covering the first gate layer 31 is formed in the gate trench 11 , and the second gate material layer 320 fills up the gate trench 11.

Then referring to FIG. 7G, the second gate material layer 320 is etched back to form the second gate layer 32.

In an embodiment, the x is equal to 0, and the material of the second gate layer 32 includes Ti. That is, in the process for forming the second gate layer 32, N₂ is not introduced. Therefore, the material of the second gate layer 32 is Ti.

In an embodiment, the material of the second gate layer 32 includes a mixed material of TiNₓ and Ti, where 0<x<1.

Subsequently, referring to FIG. 7H, an insulating dielectric layer 40 covering the second gate layer 32 and filling up the gate trench 11 is formed after the second gate layer 32 is formed.

The insulating dielectric layer 40 may include silicon nitride, silicon oxide, silicon oxynitride, other insulating materials or any combination thereof.

Next, referring to FIG. 7I, a contact plug is formed. The contact plug includes a first contact plug 51 and a second contact plug 52.

Specifically, the process for forming the first contact plug 51 includes: firstly forming a first contact plug opening passing through the insulating dielectric layer 40, the gate dielectric layer 20 and the substrate 10, and then forming the first contact plug 51 in the first contact plug opening.

The process for forming the second contact plug 52 includes firstly forming a second contact plug opening passing through the insulating dielectric layer 40, and then forming the second contact plug 52 in the second contact plug opening.

The first contact plug 51 may also be referred to as a source/drain contact plug, and may be electrically coupled to the source/drain. The second contact plug 52 may also be referred to as a gate contact plug, and may be electrically coupled to the metal gate.

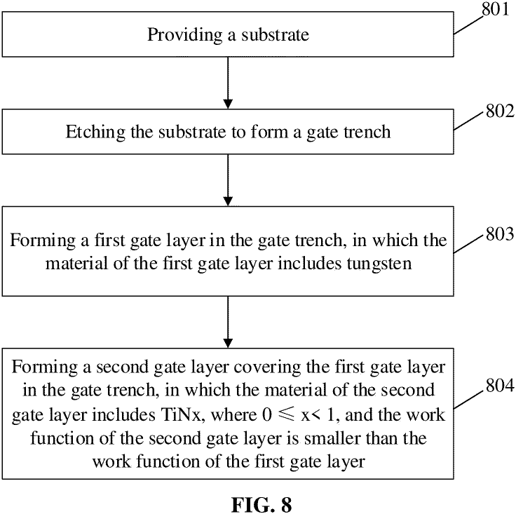

The embodiments of the present disclosure also provide a method for manufacturing a transistor, in particular, referring to FIG. 8, the method includes:
the operation 801: providing a substrate;
the operation 802: etching the substrate to form a gate trench;
the operation 803: forming a first gate layer in the gate trench, in which the material of the first gate layer includes tungsten;
the operation 804: forming a second gate layer covering the first gate layer in the gate trench, in which the material of the second gate layer includes TiNₓ, where 0 ≤ x< 1, and the work function of the second gate layer is smaller than the work function of the first gate layer.

The method for manufacturing a transistor provided by the embodiments of the present disclosure will be described in further detail below in combination with specific embodiments.

FIGS. 9A to 9I are schematic structural diagrams of devices in the process of manufacturing a transistor provided by embodiments of the disclosure

Firstly, referring to FIG. 9A, the operation 801 is performed, that is, the substrate 10 is provided.

In an embodiment, the substrate may be an elemental semiconductor material substrate (such as a silicon (Si) substrate, a germanium (Ge) substrate, etc.), a compound semiconductor material substrate (such as a silicon germanium (SiGe) substrate, etc.), or a silicon on insulator (SOI) substrate, a germanium on insulator (GeOI) substrate, etc. In the embodiments of the disclosure, the substrate may be a silicon substrate.

Before performing the operation 602, N-type doping is performed on the substrate 10 and an isolation layer 102 is formed in the substrate 10. The isolation layer 102 defines the active area 101. The isolation layer 102 may be formed by shallow trench isolation (STI) process. Specifically, the isolation trench may be formed by etching the substrate 10 and then the isolation trench is filled with a dielectric material to form the isolation layer 102.

The material of the isolation layer 102 includes silica or the like.

Subsequently, referring to FIG. 9B, the operation 802 is performed, that is, the substrate 10 is etched to form a gate trench 11.

Specifically, a mask layer may be firstly grown on the upper surface of the substrate 10, and then patterned to display a pattern of a gate trench to be etched on the mask layer, which may be patterned by a photolithography process. The mask layer may be a photoresist mask or a hard mask which may be patterned based on a photolithography mask; when the mask layer is a photoresist mask, the mask layer is patterned through the operations of exposure, development, glue removal and the like. Next, a gate trench with a certain depth is obtained by etching according to the pattern of the gate trench to be etched.

During etching to form the gate trench 11, since the material of the isolation layer 102 is silica and the material of the substrate is silicon, and the etching selectivity ratio of silica and silicon is different, so that the depth of the gate trench 11 formed by etching the isolation layer 102 is deeper than the depth of the gate trench 11 formed by etching the substrate 10.

Subsequently, referring to FIG. 9C, a gate dielectric layer 20 is formed in the gate trench 11. The gate dielectric layer 20 covers the sidewall and bottom surface of the gate trench 11. The gate dielectric layer 20 further covers part of the surface of the substrate 10.

The gate dielectric layer 20 may include silica or a high-K dielectric material.

Next, referring to FIGS. 9D to 9E, a first gate layer 31 is formed in the gate trench 11. The material of the first gate layer 31 includes tungsten.

It should be noted that, a barrier layer 33 is formed in the gate trench 11 before the first gate layer 31 is formed, and the barrier layer 33 wraps the sidewall and the bottom surface of the first gate layer 31. The material of the barrier layer includes TiN.

Specifically, referring firstly to FIG. 9D, a barrier material layer 330 and a first gate material layer 310 are formed in the gate trench 11, in which the barrier material layer 330 covers the sidewall and the bottom surface of the gate trench 11, and the first gate material layer 310 covers the barrier material layer 330 and fills up the gate trench 11.

Then referring to FIG. 9E, the barrier material layer 330 and the first gate material layer 310 are etched back to form the barrier layer 33 and the first gate layer 31, respectively. By selecting an appropriate back etching process, the upper surface of the barrier layer 33 in the gate trench 11 may be substantially flush with the upper surface of the first gate layer 31.

Next, referring to FIGS. 9F to 9G, a second gate layer 32 covering the first gate layer 31 is formed in the gate trench 11. The material of the second gate layer 32 includes TiNₓ, where 0 ≤ x< 1. The work function of the second gate layer 32 is smaller than the work function of the first gate layer 31.

Specifically, referring first to FIG. 9F, a second gate material layer 320 covering the first gate layer 31 is formed in the gate trench 11 , and the second gate material layer 320 fills up the gate trench 11.

Next, referring to FIG. 9G, the second gate material layer 320 is etched back to form the second gate layer 32.

In an embodiment, the x is equal to 0, and the material of the second gate layer 32 includes Ti. That is, in the process for forming the second gate layer 32, N₂ is not introduced. Therefore, the material of the second gate layer 32 is Ti.

In an embodiment, the material of the second gate layer 32 includes a mixed material of TiNₓ and Ti, where 0<x<1.

Subsequently, referring to FIG. 9H, an insulating dielectric layer 40 covering the second gate layer 32 and filling up the gate trench 11 is formed after the second gate layer 32 is formed.

The insulating dielectric layer 40 may include silicon nitride, silicon oxide, silicon oxynitride, other insulating materials or any combination thereof.

Next, referring to FIG. 9I, a contact plug is formed. The contact plug includes a first contact plug 51 and a second contact plug 52.

Specifically, the process for forming the first contact plug 51 includes: firstly forming a first contact plug opening passing through the insulating dielectric layer 40, the gate dielectric layer 20 and the substrate 10, and then forming the first contact plug 51 in the first contact plug opening.

The process for forming the second contact plug 52 includes: firstly forming a second contact plug opening passing through the insulating dielectric layer 40, and then forming a second contact plug 52 in the second contact plug opening.

The first contact plug 51 may also be referred to as a source/drain contact plug, and may be electrically coupled to the source/drain. The second contact plug 52 may also be referred to as a gate contact plug, and may be electrically coupled to the metal gate.

The contact plug may include polysilicon, metal silicide, metal nitride or metal.

The descriptions above are only preferred implementations of the present disclosure, and are not intended to limit the scope of protection of the present disclosure. Any modification, equivalent replacement and improvement made within the spirit and principles of the present disclosure all fall with the protection scope of the present disclosure.

In the embodiments of the present disclosure, TiN with a higher work function is used at the bottom end of the gate trench, and TiNₓ with a lower work function is used at the top end of the gate trench, which effectively reduces the electric field in the gate trench, and reduces the GIDL. In addition, compared with using polysilicon as the material of the second gate layer in some implementations, TiNₓ has a smaller resistivity than polysilicon and has a better conductivity, which is more conducive to forming a longer word line, increasing the area of the memory array of the transistor and reducing the size of the chip.

What is claimed is:

1. A transistor, comprising:
a substrate;
a gate trench located in the substrate;
a first gate layer located in the gate trench, a material of the first gate layer comprising TiN or comprising tungsten; and
a second gate layer located in the gate trench and covering the first gate layer, a material of the second gate layer comprising TiNₓ, wherein 0 ≤ x< 1, a work function of the second gate layer being smaller than a work function of the first gate layer.

2. The transistor according to claim 1, wherein,
x is equal to 0, and the material of the second gate layer comprises Ti.

3. The transistor according to claim 1, wherein,
the material of the second gate layer comprises a mixed material of TiNₓ and Ti, wherein 0<x<1.

4. The transistor according to claim 1, further comprising:
an insulating dielectric layer covering the second gate layer and filling up the gate trench.

5. The transistor according to claim 1, wherein, the material of the first gate layer comprises tungsten, and the transistor further comprises:
a barrier layer located in the gate trench and wrapping a sidewall and a bottom of the first gate layer; a material of the barrier layer comprising TiN.

6. A method for manufacturing a transistor, comprising:
providing a substrate;
etching the substrate to form a gate trench;
forming a first gate layer in the gate trench, a material of the first gate layer comprising TiN or comprising tungsten; and
forming a second gate layer covering the first gate layer in the gate trench, a material of the second gate layer comprising TiNₓ, wherein 0 ≤ x< 1, a work function of the second gate layer being smaller than a work function of the first gate layer.

7. The method according to claim 6, wherein,
x is equal to 0, and the material of the second gate layer comprises Ti.

8. The method according to claim 6, wherein,
the second gate layer comprises a mixed material of TiNₓ and Ti, wherein 0<x<1.

9. The method according to claim 6, further comprising:
forming an insulating dielectric layer covering the second gate layer and filling up the gate trench after forming the second gate layer.

10. The method according to claim 6, wherein, the material of the first gate layer comprises tungsten, and the method further comprises:
forming a barrier layer in the gate trench before forming the first gate layer; the barrier layer wrapping a sidewall and a bottom of the first gate layer; and
a material of the barrier layer comprising TiN.
